(19) United States
(12) Patent Application Publication
(10) Pub. No.: US 2025/0023563 A1
(43) Pub. Date: Jan. 16, 2025

(54) SEMICONDUCTOR DEVICE

(71) Applicant: LAPIS Technology Co., Ltd., Yokohama (JP)

(72) Inventor: Yukio KAWAMURA, Yokohama (JP)

(73) Assignee: LAPIS Technology Co., Ltd., Yokohama (JP)

(21) Appl. No.: 18/770,625

(22) Filed: Jul. 11, 2024

(30) Foreign Application Priority Data
Jul. 13, 2023 (JP) 2023-115458

(51) Int. Cl. H03K 17/56; G05F 1/56

(52) U.S. Cl. CPC H03K 17/56; G05F 1/56

(57) ABSTRACT

A semiconductor device includes first upper and lower arms, second upper and lower arms disposed in parallel, and a voltage control circuit. The first upper and lower arms include first and second switch elements connected in series and output a first signal by operating the first and second switch elements complementarily, the first switch element being on a first potential side and the second switch element being on a lower second potential side. The second upper and lower arms include third and fourth switch elements connected in series and output a second signal having a potential changing complementarily with the first signal by operating the third and fourth switch elements complementarily, the third switch element being on the first potential side, and the fourth switch element being on the second potential side. The voltage control circuit limits voltage amplitudes of the first and second signals based on a bias voltage.

### CROSS-REFERENCE TO RELATED APPLICATION

This application claims the priority benefit of Japan application serial no. 2023-115458, filed on Jul. 13, 2023. The entirety of the above-mentioned patent application is hereby incorporated by reference herein and made a part of this specification.

### BACKGROUND

### Technical Field

The present disclosure relates to a semiconductor device.

### Related Art

Patent Document 1 (Japanese Patent Application Laid-Open No. 2000-031810) discloses a driver circuit utilizing a low voltage differential signal (LVDS) interface to realize high-speed data transfer (see FIG. 1 of Patent Document 1). The driver circuit is connected to a pair of transmission paths that transmit differential signals to a reception circuit. The pair of transmission paths are provided with resistors serving as terminal resistors for setting voltage amplitudes of the differential signals. With a current from a current source flowing through the resistors, a potential difference is generated between the pair of transmission paths. In the conventional art, voltage amplitudes of the differential signals are set by changing the value of the resistors or the value of the current source.

However, in the conventional art, since the voltage amplitudes of the differential signals are set using resistors provided outside the driver circuit and resistors provided on the reception circuit side are used, the configuration of the system including the reception circuit becomes complex, and a yield may decrease. Further, the resistors may become a hindrance to the need for shortening a manufacturing time of the system including the reception circuit. Further, appropriate voltage amplitudes of differential signals may not be obtained by simply changing the value of the current source on the driver circuit side without replacing the resistors. Thus, in the conventional art, there is room for improvement in terms of appropriately changing voltage amplitudes of differential signals.

### SUMMARY

According to an embodiment of the disclosure, a semiconductor device includes first upper and lower arms, second upper and lower arms, and a voltage control circuit. The first upper and lower arms include a first switch element and a second switch element and output a first signal by operating the first switch element and the second switch element complementarily, and the first switch element is on a side of a first potential, and the second switch element is on a side of a second potential lower than the first potential and is connected in series with the first switch element. The second upper and lower arms are disposed in parallel with the first upper and lower arms, include a third switch element and a fourth switch element, and generate and output a second signal having a potential that changes complementarily with respect to the first signal by operating the third switch element and the fourth switch element complementarily, and the third switch element is on the side of the first potential, and the fourth switch element is on the side of the second potential and is connected in series with the third switch element. The voltage control circuit is connected to the first upper and lower arms and the second upper and lower arms and limits voltage amplitudes of the first signal and the second signal based on a bias voltage.

### BRIEF DESCRIPTION OF DRAWINGS

FIG. 1 is a view showing a configuration of a display device according to an embodiment of the present disclosure.

FIG. 2 is a view showing a configuration of a communication system according to an embodiment of the present disclosure.

FIG. 3 is a view showing a configuration of a transmission circuit according to an embodiment of the present disclosure.

FIG. 4 is a timing chart for illustrating an action of the transmission circuit.

FIG. 5 is a view showing a configuration of a transmission circuit according to a first modification example.

FIG. 6 is a view showing a configuration of a transmission circuit according to a second modification example.

FIG. 7 is a timing chart for illustrating an action of the transmission circuit according to the second modification example.

FIG. 8 is a view showing a configuration of a transmission circuit according to a third modification example.

### DESCRIPTION OF EMBODIMENTS

Embodiments of the present disclosure provide a semiconductor device capable of appropriately changing voltage amplitudes of differential signals without using resistors.

Hereinafter, embodiments will be described based on the drawings. The same functions or configurations will be labeled with the same or similar reference signs, and descriptions thereof will be omitted as appropriate.

### Embodiments

### (Display Device)

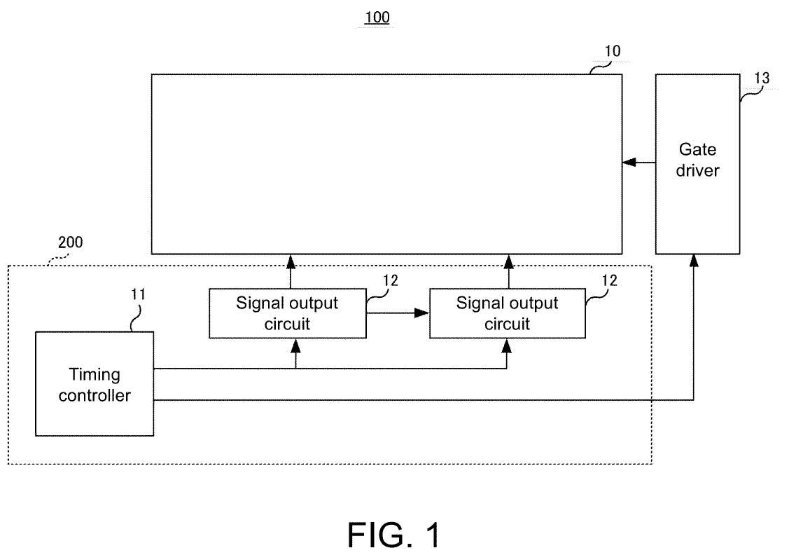

FIG. 1 is a view showing a configuration of a display device according to an embodiment of the present disclosure. A display device 100 may be interpreted as an in-vehicle display device mounted on an automobile or the like. The display device 100 includes a display panel 10, a timing controller 11, driver integrated circuits (IC) 12 (also referred to as signal output circuits), and a gate driver 13.

The display panel 10 may be interpreted as an image display device such as a liquid crystal display panel or an organic electroluminescence (EL) panel.

The timing controller 11 may control a display timing of an image on the display panel by controlling a plurality of driver ICs 12 and the gate driver 13. The timing controller 11 may generate and supply clock signals to the driver ICs 12. The timing controller 11 may supply scan control signals synchronized with video data to the gate driver 13. The timing controller 11 may be interpreted as a semiconductor device including a transmission circuit to be described later. The transmission circuit may be interpreted as a driver circuit.

The driver IC 12 may control a lighting state of a plurality of light-emitting elements provided on the display panel 10. The gate driver 13 may generate gate signals based on signals supplied from the timing controller 11 and supply the gate signals to the display panel 10.

The timing controller 11 and the driver ICs 12 may constitute a communication system 200. The communication system 200 may be interpreted as a system to which mini-LVDS is applied.

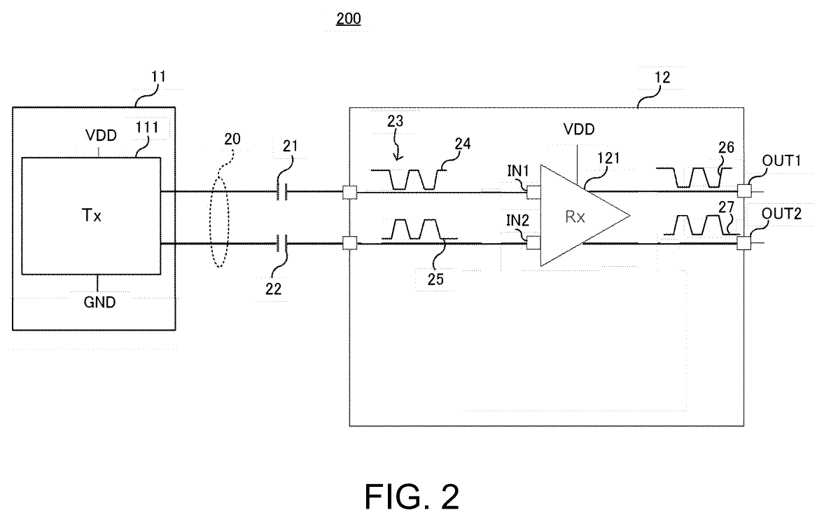

Next, referring to FIG. 2, a configuration of the communication system 200 will be described. FIG. 2 is a view showing a configuration of a communication system according to an embodiment of the present disclosure. The communication system 200 includes a timing controller 11 and a signal output circuit 12. The timing controller 11 and the signal output circuit 12 are communicatively connected via a transmission path 20.

The timing controller 11 includes a transmission circuit 111. The transmission circuit 111 may be interpreted as a semiconductor device that outputs differential signals 23. The transmission circuit 111 may also be interpreted as a circuit that transmits data using the differential signals 23. The transmission circuit 111 may also be applied to devices other than the timing controller 11.

The differential signals 23 include two signals that change complementarily to each other. Specifically, the differential signals 23 include a first signal 24 transmitted via a first capacitive element 21 disposed in the transmission path 20, and a second signal 25 transmitted via a second capacitive element 22 disposed in the transmission path 20. The second signal 25 may be interpreted as a signal having a potential that changes complementarily with respect to the first signal 24.

The signal output circuit 12 includes a reception circuit 121. The reception circuit 121 may be interpreted as a data reception circuit based on AC coupling, to which the differential signals 23 transmitted via capacitive elements are supplied. The AC coupling may be interpreted as a method of removing a DC component of an input signal and transmitting only an AC component to the reception circuit 121. The reception circuit 121 includes a first input terminal IN1 to which the first signal 24 is inputted, and a second input terminal IN2 to which the second signal 25 is inputted. The first input terminal IN1 may be interpreted as a positive terminal (+terminal), and the second input terminal IN2 may be interpreted as a negative terminal (−terminal).

The reception circuit 121 outputs a first logic signal 26 corresponding to a potential of the first signal 24, and a second logic signal 27 corresponding to a potential of the second signal 25. Specifically, the reception circuit 121 may amplify the first signal 24 and the second signal 25, and output the first logic signal 26 and the second logic signal 27 having voltage levels higher than the first signal 24 and the second signal 25. The first logic signal 26 is transmitted to the display panel 10 shown in FIG. 1 via a first output terminal OUT1, and the second logic signal 27 is transmitted to the display panel 10 shown in FIG. 1 via a second output terminal OUT2.

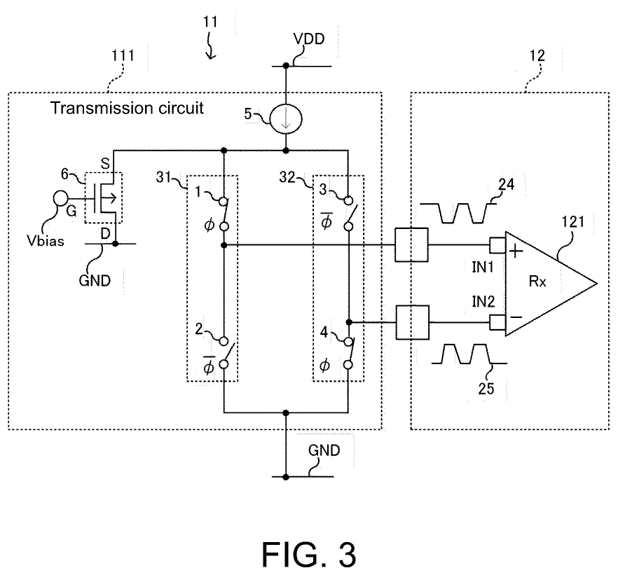

Next, referring to FIG. 3, a specific configuration of the transmission circuit 111 will be described. FIG. 3 is a view showing a configuration of a transmission circuit according to an embodiment of the present disclosure. The transmission circuit 111 includes first upper and lower arms 31, second upper and lower arms 32, and a voltage control circuit 6.

### (First Upper and Lower Arms)

The first upper and lower arms 31 may be interpreted as a circuit that includes a first switch element 1 and a second switch element 2 connected in series. Specifically, the first upper and lower arms 31 may be interpreted as a circuit that includes the first switch element 1 on a first potential side, and the second switch element 2 on a second potential side lower than the first potential, connected in series with the first switch element 1. With the first switch element 1 and the second switch element 2 acting complementarily, the first upper and lower arms 31 may output the first signal 24.

The first potential may be interpreted as a potential of a power supply VDD, and the second potential may be interpreted as a potential of a ground GND. Each of the first switch element 1 and the second switch element 2 may be interpreted as a transistor.

### (Second Upper and Lower Arms)

The second upper and lower arms 32 may be interpreted as a circuit disposed in parallel with the first upper and lower arms 31, and may be interpreted as a circuit that includes a third switch element 3 and a fourth switch element 4 connected in series. Specifically, the second upper and lower arms 32 may be interpreted as a circuit that includes the third switch element 3 on the first potential side, and the fourth switch element 4 on the second potential side lower than the first potential, connected in series with the third switch element 3. With the third switch element 3 and the fourth switch element 4 acting complementarily, the second upper and lower arms 32 may output the second signal 25. Each of the third switch element 3 and the fourth switch element 4 may be interpreted as a transistor.

Respective on-off actions of each switch element from the first switch element 1 to the fourth switch element 4 are controlled by a control circuit (not shown).

In FIG. 3, the first switch element 1 and the fourth switch element 4 are in an on state, and the second switch element 2 and the third switch element 3 are in an off state. In this case, a current from a current source 5 flows in the sequence of the first switch element 1, the first input terminal IN1, the second input terminal IN2, the fourth switch element 4, and the ground GND.

In contrast, in the case where the first switch element 1 and the fourth switch element 4 are in an off state, and the second switch element 2 and the third switch element 3 are in an on state, the current from the current source 5 flows in the sequence of the fourth switch element 4, the second input terminal IN2, the first input terminal IN1, the second switch element 2, and the ground GND.

### (Voltage Control Circuit)

The voltage control circuit 6 may be interpreted as a control circuit that controls voltage amplitudes of the differential signals 23. The voltage control circuit 6 may be interpreted as a circuit that is connected to the first upper and lower arms 31 and the second upper and lower arms 32, and limits the voltage amplitudes of the first signal 24 and the second signal 25 based on a bias voltage Vbias.

Specifically, the voltage control circuit 6 may be interpreted as a transistor connected between the current source 5 provided at the first potential (power supply VDD) and the first switch element 1, and further connected between the current source 5 and the third switch element 3.

More specifically, the voltage control circuit 6 may be interpreted as an enhancement-type P-channel transistor having a gate G to which the bias voltage Vbias is applied, a drain D that is grounded, and a source S that is connected to the current source 5, one terminal of the first switch element 1, and one terminal of the third switch element 3.

The bias voltage Vbias may be interpreted as a voltage generated by a voltage generation circuit (not shown). The bias voltage Vbias may be interpreted as a voltage that defines respective voltage amplitudes of the first signal 24 and the second signal 25. The bias voltage Vbias may be interpreted as a voltage that limits the voltages applied to the first upper and lower arms 31 and the second upper and lower arms 32 to specific potentials.

### (Action of Transmission Circuit)

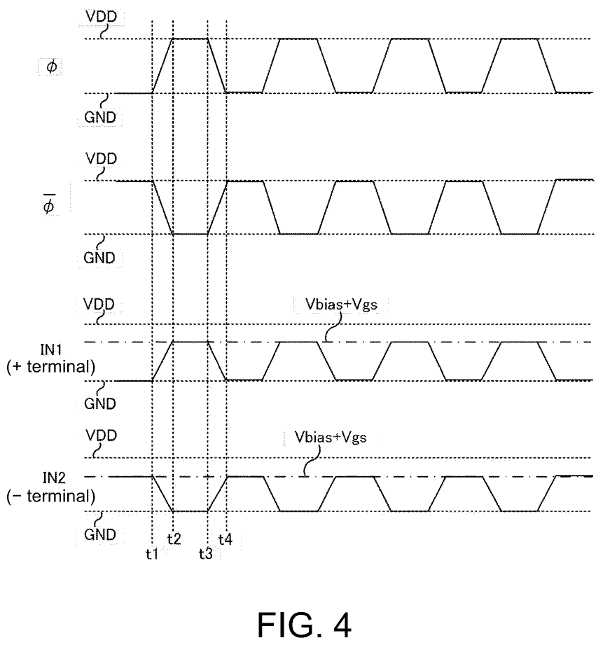

Next, referring to FIG. 4, an action of the transmission circuit 111 will be described. FIG. 4 is a timing chart for illustrating the action of the transmission circuit. FIG. 4 shows a clock signal (ϕ) inputted to a first arm or a second arm from a control circuit (not shown), a clock signal (/ϕ) inputted to the first arm or the second arm from the control circuit (not shown), the first signal 24 inputted to the first input terminal IN1, and the second signal 25 inputted to the second input terminal IN2. The clock signal (/ϕ) may be interpreted as a signal having a potential that changes complementarily with respect to the clock signal (ϕ).

At a time t1, when the first switch element 1 and the fourth switch element 4 turn on according to the clock signal ϕ, and the second switch element 2 and the third switch element 3 turn off according to the clock signal/ϕ, the voltage of the first signal 24 rises, and the voltage of the second signal 25 drops.

At a time t2 after a period has elapsed from the time t1, when the voltage of the first signal 24 reaches a specific voltage, with a current flowing through the voltage control circuit 6, the rise in the voltage amplitude of the first signal 24 is suppressed. The specific voltage may be interpreted as a voltage obtained by adding a gate-source voltage Vgs of the transistor in the voltage control circuit 6 to the bias voltage Vbias. The specific voltage may also be interpreted as a voltage for causing the current from the current source 5 to flow through the voltage control circuit 6, i.e., diverting the current to the voltage control circuit 6. By changing the bias voltage, the voltage amplitude of the first signal 24 can be changed.

At a time t3 after a period has elapsed from the time t2, when the first switch element 1 and the fourth switch element 4 turn off according to the clock signal ϕ, and the second switch element 2 and the third switch element 3 turn on according to the clock signal /ϕ, the voltage of the second signal 25 rises, and the voltage of the first signal 24 drops.

At a time t4 after a period has elapsed from the time t3, when the voltage of the second signal 25 reaches a specific voltage, with a current flowing through the voltage control circuit 6, the rise in the voltage amplitude of the second signal 25 is suppressed. As mentioned above, the specific voltage may be interpreted as a voltage obtained by adding the gate-source voltage Vgs to the bias voltage Vbias, and may also be interpreted as a voltage that causes the current from the current source 5 to flow through the voltage control circuit 6. By changing the bias voltage, the voltage amplitude of the second signal 25 can be changed.

In this manner, the transmission circuit 111 of the present disclosure can change the voltage amplitudes of the differential signals by setting the bias voltage Vbias. In contrast, in the conventional art, resistors are provided outside a driver circuit corresponding to the transmission circuit 111, and voltage amplitudes of differential signals are set using the resistors. Thus, the configuration of the system including the reception circuit becomes complex, and a yield may decrease. Further, the resistors may become a hindrance to the need for shortening a manufacturing time of the system including the reception circuit. Further, appropriate voltage amplitudes of differential signals may not be obtained by simply changing the value of the current source on the driver circuit side without replacing the resistors.

### Effect

The transmission circuit 111 of the present disclosure includes the voltage control circuit 6 which limits the voltage amplitudes of the differential signals based on the bias voltage. With this configuration, the voltage amplitudes of the differential signals can be changed without providing resistors outside the driver circuit. Thus, high-speed communication limiting voltage amplitudes of differential signals can be realized while simplifying the configuration of the system including the reception circuit.

Further, because the configuration of the system including the reception circuit is simplified, the yield may improve. Further, it also becomes possible to shorten the manufacturing time of the system including the reception circuit. Further, it is possible to easily change the voltage amplitudes of the differential signals without replacing resistors. Further, it is possible to easily change the voltage amplitudes of the differential signals without changing the current of the current source 5.

### First Modification Example

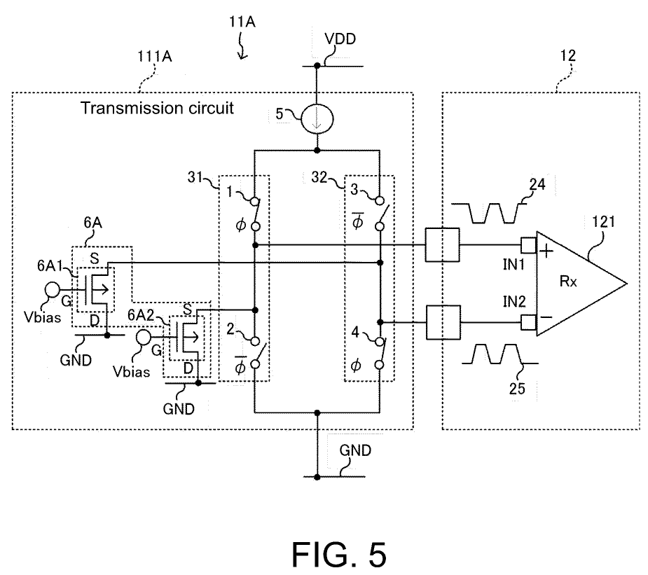

FIG. 5 is a view showing a configuration of a transmission circuit according to a first modification example. The difference from the transmission circuit 111 shown in FIG. 3 is that, in a transmission circuit 111A according to the first modification example, a voltage control circuit 6A includes a first voltage control circuit 6A1 and a second voltage control circuit 6A2.

The first voltage control circuit 6A1 may be interpreted as a transistor connected between the third switch element 3 and the fourth switch element 4. Specifically, the first voltage control circuit 6A1 may be interpreted as an enhancement-type P-channel transistor having a gate G to which the bias voltage Vbias is applied, a drain D that is grounded, and a source S that is connected to the other terminal of the third switch element 3 and one terminal of the fourth switch element 4.

The second voltage control circuit 6A2 may be interpreted as a transistor connected between the first switch element 1 and the second switch element 2. Specifically, the second voltage control circuit 6A2 may be interpreted as an enhancement-type P-channel transistor having a gate G to which the bias voltage Vbias is applied, a drain D that is grounded, and a source S that is connected to the other terminal of the first switch element 1 and one terminal of the second switch element 2.

The transmission circuit 111A according to the first modification example may act in the same manner as the transmission circuit 111 shown in FIG. 3. That is, at the time t2 shown in FIG. 4, when the voltage of the first signal 24 reaches a specific voltage, with a current flowing through the second voltage control circuit 6A2, the rise in the voltage amplitude of the first signal 24 is suppressed. The specific voltage may be interpreted as a voltage obtained by adding the gate-source voltage Vgs of the transistor constituting the second voltage control circuit 6A2 to the bias voltage Vbias. The specific voltage may also be interpreted as a voltage for causing the current from the current source 5 to flow through the second voltage control circuit 6A2, i.e., diverting the current to the second voltage control circuit 6A2. By changing the bias voltage, the voltage amplitude of the first signal 24 can be changed.

Further, at the time t4 shown in FIG. 4, when the voltage of the second signal 25 reaches a specific voltage, with a current flowing through the first voltage control circuit 6A1, the rise in the voltage amplitude of the second signal 25 is suppressed. As mentioned above, the specific voltage may be interpreted as a voltage obtained by adding the gate-source voltage Vgs of the transistor constituting the first voltage control circuit 6A1 to the bias voltage Vbias, and may also be interpreted as a voltage that causes the current from the current source 5 to flow through the first voltage control circuit 6A1. By changing the bias voltage, the voltage amplitude of the second signal 25 can be changed.

So far, the configuration example of a transmission circuit for defining the upper limit of the voltage amplitudes of the differential signals has been described. Hereinafter, configuration examples (second modification example and third modification example) of a transmission circuit that also defines the lower limit of the voltage amplitudes will be described.

### Second Modification Example

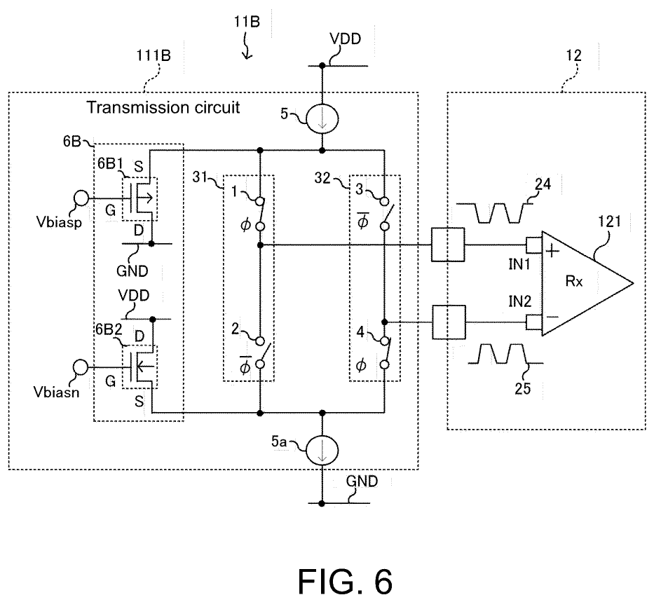

FIG. 6 is a view showing a configuration of a transmission circuit according to a second modification example. The difference from the transmission circuit 111 shown in FIG. 3 is that, in a transmission circuit 111B according to the second modification example, a voltage control circuit 6B includes a first voltage control circuit 6B1 and a second voltage control circuit 6B2. In the transmission circuit 111B, the other terminal of the second switch element 2 and the other terminal of the fourth switch element 4 are connected to a current source 5a on the second potential side.

The first voltage control circuit 6B1 includes a first conductivity type transistor. The first conductivity type transistor may be interpreted as a transistor connected between a first current source provided at the first potential and the first switch element 1, and connected between the first current source and the third switch element 3. The first current source may be interpreted as the current source 5. Specifically, the first voltage control circuit 6B1 may be interpreted as a transistor connected between the current source 5 provided at the first potential and the first switch element 1, and connected between the current source 5 and the third switch element 3. More specifically, the first voltage control circuit 6B1 may be interpreted as an enhancement-type P-channel transistor having a gate G to which a bias voltage Vbiasp is applied, a drain D that is grounded, and a source S that is connected to the current source 5, one terminal of the first switch element 1, and one terminal of the third switch element 3.

The second voltage control circuit 6B2 includes a second conductivity type transistor. The second conductivity type transistor may be interpreted as a transistor connected between a second current source provided at the second potential and the second switch element 2, and connected between the second current source and the fourth switch element 4. The second current source may be interpreted as the current source 5a. Specifically, the second voltage control circuit 6B2 may be interpreted as a transistor connected between the current source 5a provided at the second potential and the second switch element 2, and connected between the current source 5a and the fourth switch element 4. More specifically, the second voltage control circuit 6B2 may be interpreted as an enhancement-type N-channel transistor having a gate G to which a bias voltage Vbiasn is applied, a drain D that is connected to the power supply VDD, and a source S that is connected to the current source 5a, the other terminal of the second switch element 2, and the other terminal of the fourth switch element 4.

### Action of Transmission Circuit According to Second Modification Example

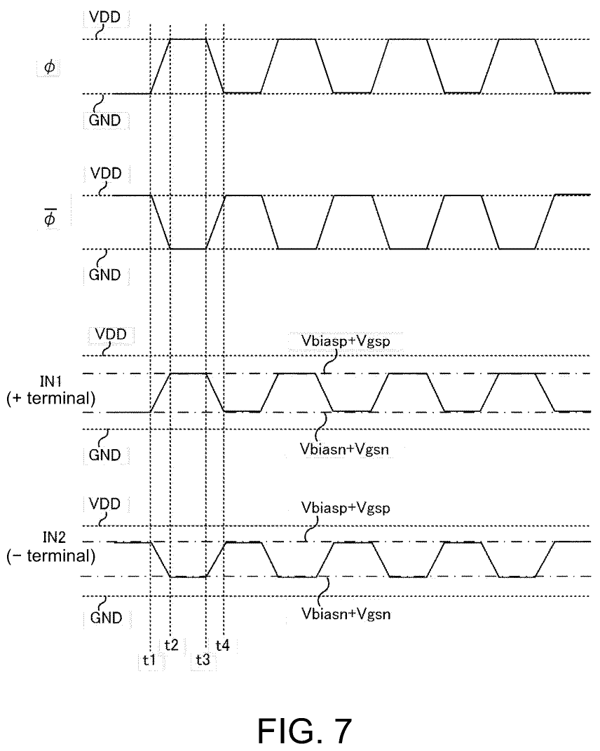

Next, an action of the transmission circuit 111B will be described with reference to FIG. 7. FIG. 7 is a timing chart for illustrating the action of the transmission circuit according to the second modification example. FIG. 7 shows a clock signal (ϕ) inputted to the first arm or the second arm from a control circuit (not shown), a clock signal (/ϕ) inputted to the first arm or the second arm from the control circuit (not shown), the first signal 24 inputted to the first input terminal IN1, and the second signal 25 inputted to the second input terminal IN2.

At a time t1, when the first switch element 1 and the fourth switch element 4 turn on according to the clock signal ϕ, and the second switch element 2 and the third switch element 3 turn off according to the clock signal/o, the voltage of the first signal 24 rises, and the voltage of the second signal 25 drops.

At a time t2 after a period has elapsed from the time t1, when the voltage of the first signal 24 reaches a specific voltage, with a current flowing through the first voltage control circuit 6B1, the rise in the voltage amplitude of the first signal 24 is suppressed. The specific voltage may be interpreted as a voltage obtained by adding a gate-source voltage Vgsp of the transistor in the first voltage control circuit 6B1 to the bias voltage Vbiasp applied to the first voltage control circuit 6B1. The specific voltage may also be interpreted as a voltage for causing the current from the current source 5 to flow through the first voltage control circuit 6B1, i.e., diverting the current to the first voltage control circuit 6B1. By changing the bias voltage Vbiasp, the voltage amplitude of the first signal 24 can be changed.

At a time t3 after a period has elapsed from the time t2, when the first switch element 1 and the fourth switch element 4 turn off according to the clock signal ϕ, and the second switch element 2 and the third switch element 3 turn on according to the clock signal/o, the voltage of the second signal 25 rises, and the voltage of the first signal 24 drops.

At a time t4 after a period has elapsed from the time t3, when the voltage of the second signal 25 reaches a specific voltage, with a current flowing through the second voltage control circuit 6B2, the drop in the voltage amplitude of the second signal 25 is suppressed. As mentioned above, the specific voltage may be interpreted as a voltage obtained by adding a gate-source voltage Vgsn to the bias voltage Vbiasn applied to the second voltage control circuit 6B2, and may also be interpreted as a voltage that causes the current from the current source 5 to flow through the second voltage control circuit 6B2. By changing the bias voltage Vbiasn, the voltage amplitude of the second signal 25 can be changed.

By changing the bias voltage Vbiasp and the bias voltage Vbiasn, the transmission circuit 111B can change the upper limit and the lower limit of the voltage amplitudes of the differential signals. According to the transmission circuit 111B, since the voltage amplitudes of the differential signals may be fine-tuned, higher-speed data transmission may be realized.

### Third Modification Example

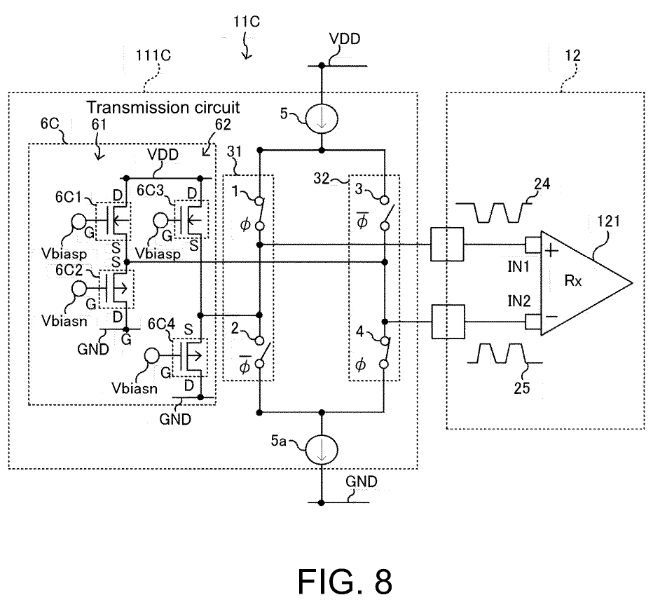

FIG. 8 is a view showing a configuration of a transmission circuit according to a third modification example. The difference from the transmission circuit 111B shown in FIG. 6 is that, in a transmission circuit 111C according to the third modification example, a voltage control circuit 6C includes a first transistor pair 61 and a second transistor pair 62. Specifically, the voltage control circuit 6C includes a first voltage control circuit 6C1, a second voltage control circuit 6C2, a third voltage control circuit 6C3, and a fourth voltage control circuit 6C4.

The first transistor pair 61 may be interpreted as a transistor pair that includes a first conductivity type transistor and a second conductivity type transistor connected in series between the first potential and the second potential, and is connected between the third switch element 3 and the fourth switch element 4. The second transistor pair 62 may be interpreted as a transistor pair that includes a first conductivity type transistor and a second conductivity type transistor connected in series between the first potential and the second potential, and is connected between the first switch element 1 and the second switch element 2.

The first voltage control circuit 6C1 may be interpreted as a transistor connected between the third switch element 3 and the fourth switch element 4. Specifically, the first voltage control circuit 6C1 may be interpreted as an enhancement-type N-channel transistor having a gate G to which the bias voltage Vbiasp is applied, a drain D that is connected to the power supply VDD, and a source S that is connected to the other terminal of the third switch element 3 and one terminal of the fourth switch element 4 and is connected to a source S of the second voltage control circuit 6C2.

The second voltage control circuit 6C2 may be interpreted as a transistor connected between the third switch element 3 and the fourth switch element 4. Specifically, the second voltage control circuit 6C2 may be interpreted as an enhancement-type P-channel transistor having a gate G to which the bias voltage Vbiasn is applied, a drain D that is grounded, and a source S that is connected to the other terminal of the third switch element 3 and one terminal of the fourth switch element 4 and is connected to the source S of the first voltage control circuit 6C1.

The third voltage control circuit 6C3 may be interpreted as a transistor connected between the first switch element 1 and the second switch element 2. Specifically, the third voltage control circuit 6C3 may be interpreted as an enhancement-type N-channel transistor having a gate G to which the bias voltage Vbiasp is applied, a drain D that is connected to the power supply VDD, and a source S that is connected to the other terminal of the first switch element 1 and one terminal of the second switch element 2 and is connected to a source S of the fourth voltage control circuit 6C4.

The fourth voltage control circuit 6C4 may be interpreted as a transistor connected between the first switch element 1 and the second switch element 2. Specifically, the fourth voltage control circuit 6C4 may be interpreted as an enhancement-type P-channel transistor having a gate G to which the bias voltage Vbiasn is applied, a drain D that is grounded, and a source S that is connected to the other terminal of the first switch element 1 and one terminal of the second switch element 2 and is connected to the source S of the third voltage control circuit 6C3.

The transmission circuit 111C according to the third modification example may act in the same manner as the transmission circuit 111B shown in FIG. 6. That is, at the time t2 shown in FIG. 7, when the voltage of the first signal 24 reaches a specific voltage, with a current flowing through the fourth voltage control circuit 6C4, the rise in the voltage amplitude of the first signal 24 is suppressed. The specific voltage may be interpreted as a voltage obtained by adding the gate-source voltage Vgsn of the transistor constituting the fourth voltage control circuit 6C4 to the bias voltage Vbiasn. The specific voltage may also be interpreted as a voltage for causing the current from the current source 5 to flow through the fourth voltage control circuit 6C4, i.e., diverting the current to the fourth voltage control circuit 6C4. By changing the bias voltage, the upper limit of the voltage amplitude of the first signal 24 can be changed.

At the time t2 shown in FIG. 7, when the voltage of the second signal 25 reaches a specific voltage, with a current flowing through the first voltage control circuit 6C1, the drop in the voltage amplitude of the second signal 25 is suppressed. The specific voltage may be interpreted as a voltage obtained by adding the gate-source voltage Vgsp of the transistor constituting the first voltage control circuit 6C1 to the bias voltage Vbiasp. The specific voltage may also be interpreted as a voltage for causing the current from the current source 5a to flow through the first voltage control circuit 6C1, i.e., diverting the current to the first voltage control circuit 6C1. By changing the bias voltage, the lower limit of the voltage amplitude of the second signal 25 can be changed.

At the time t4 shown in FIG. 7, when the voltage of the first signal 24 reaches a specific voltage, with a current flowing through the third voltage control circuit 6C3, the drop in the voltage amplitude of the first signal 24 is suppressed. The specific voltage may be interpreted as a voltage obtained by adding the gate-source voltage Vgsp of the transistor constituting the third voltage control circuit 6C3 to the bias voltage Vbiasp. The specific voltage may also be interpreted as a voltage for causing the current from the current source 5a to flow through the third voltage control circuit 6C3, i.e., diverting the current to the third voltage control circuit 6C3. By changing the bias voltage, the lower limit of the voltage amplitude of the first signal 24 can be changed.

At the time t4 shown in FIG. 7, when the voltage of the second signal 25 reaches a specific voltage, with a current flowing through the second voltage control circuit 6C2, the rise in the voltage amplitude of the second signal 25 is suppressed. The specific voltage may be interpreted as a voltage obtained by adding the gate-source voltage Vgsn of the transistor constituting the second voltage control circuit 6C2 to the bias voltage Vbiasn. The specific voltage may also be interpreted as a voltage for causing the current from the current source 5 to flow through the second voltage control circuit 6C2, i.e., diverting the current to the second voltage control circuit 6C2. By changing the bias voltage, the upper limit of the voltage amplitude of the second signal 25 can be changed.

The following supplementary notes are further disclosed in association with the above description.

### (Supplementary Note 1)

A semiconductor device outputting differential signals, the semiconductor device including:
first upper and lower arms that include a first switch element and a second switch element and output a first signal by operating the first switch element and the second switch element complementarily, wherein the first switch element is on a side of a first potential, and the second switch element is on a side of a second potential lower than the first potential and is connected in series with the first switch element;
second upper and lower arms that are disposed in parallel with the first upper and lower arms, include a third switch element and a fourth switch element, and generate and output a second signal having a potential that changes complementarily with respect to the first signal by operating the third switch element and the fourth switch element complementarily, wherein the third switch element is on the side of the first potential, and the fourth switch element is on the side of the second potential and is connected in series with the third switch element; and
a voltage control circuit that is connected to the first upper and lower arms and the second upper and lower arms and limits voltage amplitudes of the first signal and the second signal based on a bias voltage.

### (Supplementary Note 2)

The semiconductor device according to Supplementary Note 1, wherein
the voltage control circuit is connected between a current source provided at the first potential and the first switch element, and is connected between the current source and the third switch element.

### (Supplementary Note 3)

The semiconductor device according to Supplementary Note 1 or 2, wherein
the voltage control circuit includes:
a first voltage control circuit connected between the third switch element and the fourth switch element; and
a second voltage control circuit connected between the first switch element and the second switch element.

### (Supplementary Note 4)

The semiconductor device according to any one of Supplementary Notes 1 to 3, wherein
the voltage control circuit includes:
a first voltage control circuit including a first conductivity type transistor that is connected between a first current source provided at the first potential and the first switch element and is connected between the first current source and the third switch element; and a second voltage control circuit including a second conductivity type transistor that is connected between a second current source provided at the second potential and the second switch element and is connected between the second current source and the fourth switch element.

### (Supplementary Note 5)

The semiconductor device according to any one of Supplementary Notes 1 to 4, wherein
the voltage control circuit includes:
a first transistor pair that includes a first conductivity type transistor and a second conductivity type transistor connected in series between the first potential and the second potential, and is connected between the third switch element and the fourth switch element; and
a second transistor pair that includes a first conductivity type transistor and a second conductivity type transistor connected in series between the first potential and the second potential, and is connected between the first switch element and the second switch element.

What is claimed is:

1. A semiconductor device outputting differential signals, the semiconductor device comprising:
first upper and lower arms that comprise a first switch element and a second switch element and output a first signal by operating the first switch element and the second switch element complementarily, wherein the first switch element is on a side of a first potential, and the second switch element is on a side of a second potential lower than the first potential and is connected in series with the first switch element;
second upper and lower arms that are disposed in parallel with the first upper and lower arms, comprise a third switch element and a fourth switch element, and generate and output a second signal having a potential that changes complementarily with respect to the first signal by operating the third switch element and the fourth switch element complementarily, wherein the third switch element is on the side of the first potential, and the fourth switch element is on the side of the second potential and is connected in series with the third switch element; and
a voltage control circuit that is connected to the first upper and lower arms and the second upper and lower arms and limits voltage amplitudes of the first signal and the second signal based on a bias voltage.

2. The semiconductor device according to claim 1, wherein
the voltage control circuit is connected between a current source provided at the first potential and the first switch element, and is connected between the current source and the third switch element.

3. The semiconductor device according to claim 1, wherein
the voltage control circuit comprises:
a first voltage control circuit connected between the third switch element and the fourth switch element; and
a second voltage control circuit connected between the first switch element and the second switch element.

4. The semiconductor device according to claim 1, wherein
the voltage control circuit comprises:
a first voltage control circuit comprising a first conductivity type transistor that is connected between a first current source provided at the first potential and the first switch element and is connected between the first current source and the third switch element; and
a second voltage control circuit comprising a second conductivity type transistor that is connected between a second current source provided at the second potential and the second switch element and is connected between the second current source and the fourth switch element.

5. The semiconductor device according to claim 1, wherein
the voltage control circuit comprises:
a first transistor pair that comprises a first conductivity type transistor and a second conductivity type transistor connected in series between the first potential and the second potential, and is connected between the third switch element and the fourth switch element; and
a second transistor pair that comprises a first conductivity type transistor and a second conductivity type transistor connected in series between the first potential and the second potential, and is connected between the first switch element and the second switch element.
